(19) United States
(12) Patent Application Publication
(10) Pub. No.: US 2011/0214603 A1
(43) Pub. Date: Sep. 8, 2011

(54) METHOD OF MANUFACTURING SILICON SINGLE CRYSTAL

(75) Inventor: Toshiro MINAMI, Hadano-shi (JP)

(73) Assignee: COVALENT MATERIALS CORPORATION, Shinagawa-ku (JP)

(21) Appl. No.: 13/036,196

(22) Filed: Feb. 28, 2011

(30) Foreign Application Priority Data
Mar. 3, 2010 (JP) 2010-046509
Jun. 30, 2010 (JP) 2010-148827

(51) Int. Cl. C30B 15/14

(52) U.S. Cl. 117/13

(57) ABSTRACT

The present invention provides a method of manufacturing a silicon single crystal which can more greatly suppress a pinhole formation in the silicon single crystal, which is a method of manufacturing a silicon single crystal by the Czochralski method in which a silicon material to be silicon melt is melted in a furnace body and then a silicon single crystal is pulled up. After melting the silicon material and before the start of pulling up the silicon single crystal, a heater power is set to be higher than that during the step of pulling up the silicon single crystal, and an internal furnace pressure is set as 30 Torr or less, which is lower than that during the step of pulling up the silicon single crystal, the power and pressure being maintained for a predetermined time, and then the step of pulling up the silicon single crystal is carried out.

### BACKGROUND OF THE INVENTION

1. Field of the Invention

The present invention relates to a method of manufacturing a silicon single crystal using the Czochralski method (hereinafter referred to as the “CZ method”), and more particularly to a method of manufacturing a silicon single crystal which can suppress pinhole formation in the silicon single crystal.

2. Description of the Related Art

In recent years, when pulling up a silicon single crystal, there is a problem that bubbles exist in silicon melt tend to be trapped within a silicon single crystal and a pinhole defect tends to occur.

For such a problem, for example, in Japanese Patent Application Laid-Open (kokai) No. 5-9097 (patent document 1), a method in which polysilicon material is melted at an internal furnace pressure of from 5 to 60 millibar and then a silicon single crystal is pulled up at an internal furnace pressure of at least 100 millibar is disclosed. In Japanese Patent Application Laid-Open (kokai) No. 2000-169287 (patent document 2), a method in which polysilicon material is melted at an internal furnace pressure of from 65 to 400 millibar and then a silicon single crystal is pulled up from the silicon melt under a condition where an internal furnace pressure is lower than the pressure during the melting and not higher than 95 millibar is disclosed.

However, according to the method disclosed in the patent document 1, although incidence of pinhole defects can be decreased by performing a melting process under a reduced pressure of 5 to 60 millibar, there is still a possibility of new occurrence of bubbles during the pulling up of the silicon single crystal. Thus, it has limitation in suppression of the pinhole formation in the silicon single crystal.

In addition, according to the method disclosed in the patent document 2, generation of pinhole defects can be decreased by controlling the internal furnace pressure during the pulling up of the silicon single crystal to be lower than the internal furnace pressure during the melting process and not higher than 95 millibar. However, in the case where the internal furnace pressure during the pulling up of the silicon single crystal is lower than the pressure during the melting process, there is still a possibility of new occurrence of bubbles in the silicon melt. Thus, it has limitation in suppression of the pinhole formation in the silicon single crystal.

### SUMMARY OF THE INVENTION

The invention has been made to solve the above-mentioned technical problems, and an object thereof is to provide a method of manufacturing a silicon single crystal which can more greatly suppress the pinhole formation in the silicon single crystal.

The method of manufacturing a silicon single crystal of this invention is a method of manufacturing a silicon single crystal by the Czochralski method which comprises a step of melting a silicon material to be silicon melt in a furnace body and then a step of pulling up the silicon single crystal, wherein after the step of melting the above-mentioned silicon material and before the start of the step of pulling up the above-mentioned silicon single crystal, a heater power is set to be higher than that during the step of pulling up the above-mentioned silicon single crystal, an internal furnace pressure is set as 30 Torr or less which is lower than that during the step of pulling up the above-mentioned silicon single crystal, the above-mentioned power and pressure are maintained for a predetermined time, and then the step of pulling up the above-mentioned silicon single crystal is carried out.

The above-mentioned predetermined time is preferably from 0.5 to 60 minutes.

The above-mentioned internal furnace pressure during the step of pulling up the silicon single crystal is preferably not higher than 100 Torr.

According to the present invention, the method of manufacturing the silicon single crystal which can more greatly suppress the pinhole formation in the silicon single crystal is provided.

### BRIEF DESCRIPTION OF THE DRAWING

FIG. 1 is a schematic diagram showing one example of a silicon single crystal pulling up apparatus used for a method of manufacturing a silicon single crystal of the present invention.

FIG. 2A is a schematic graph showing one embodiment of heater power control of the method of manufacturing the silicon single crystal of the present invention.

FIG. 2B is a schematic graph showing one embodiment of internal furnace pressure control of the method of manufacturing the silicon single crystal of the present invention.

### DESCRIPTION OF THE PREFERRED EMBODIMENTS

Hereinafter, a method of manufacturing a silicon single crystal of the present invention will be explained in detail with reference to the appended drawings.

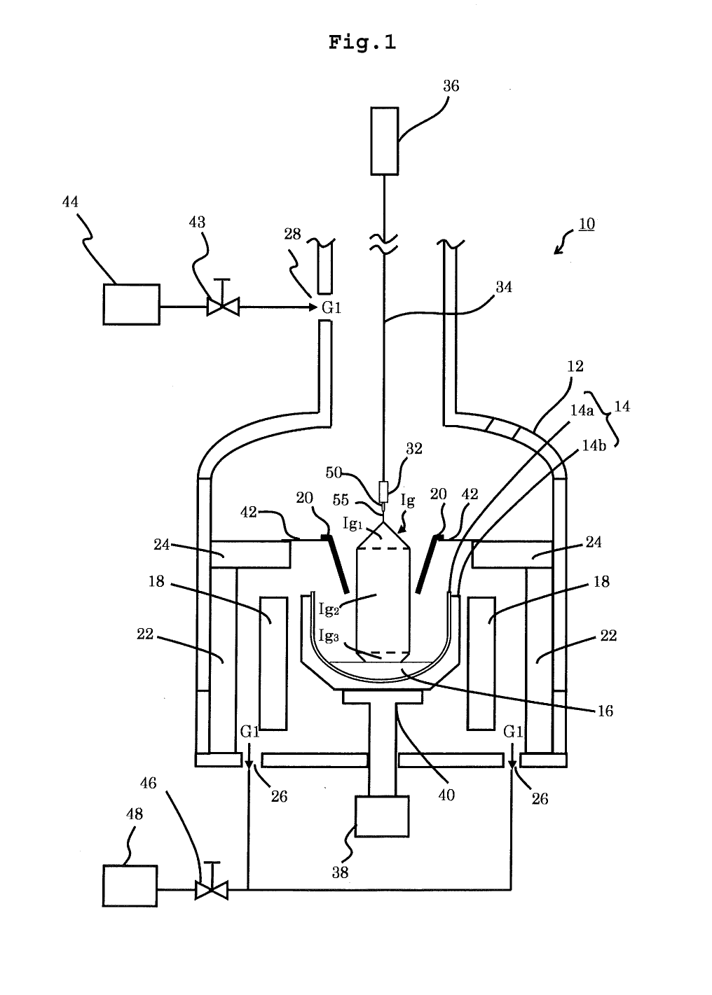

FIG. 1 is a schematic diagram showing one example of a silicon single crystal pulling up apparatus used for the method of manufacturing the silicon single crystal of the present invention.

A silicon single crystal pulling up apparatus 10 used for the method of manufacturing the silicon single crystal of the present invention includes, as shown in FIG. 1, a furnace body 12, a crucible 14 arranged in the furnace body 12 for containing a silicon material (mainly polysilicon), a heater 18 arranged at the outer periphery of the crucible 14 for heating the crucible 14 so that the silicon material contained in the crucible 14 is melted to be silicon melt 16 and a heat shield 20 in a cylindrical shape arranged above the silicon melt 16 for shielding a silicon single crystal Ig pulled up from the silicon melt 16 by the CZ method from radiant heat.

The crucible 14 is constituted by a quartz glass crucible 14a for containing the silicon melt 16 and a carbon crucible 14b for containing the quartz glass crucible 14a.

A first thermal insulating member 22 is provided at the outer periphery of the heater 18, and a second thermal insulating member 24 is provided on upper portion of the first insulating member 22 at a predetermined distance from the heater 18.

A carrier gas inlet 28 for supplying carrier gas G1 is provided above the heat shield 20. The carrier gas G1 is exhausted from an outlet 26 located below the crucible 14 to the outside of the furnace body 12 through the inner side of the heat shield 20 and between the heat shield 20 and the silicon melt 16.

In the furnace body 12, a pulling wire 34 is provided above the crucible 14. The pulling wire 34 is mounted with a seed chuck 32 for holding a seed crystal 50 used for growing the silicon single crystal Ig. The pulling wire 34 is mounted to a rotatable, liftable and lowerable wire rotary lift mechanism 36 provided outside the furnace body 12.

The crucible 14 is mounted on a crucible rotating shaft 40 which is rotatable, liftable and lowerable by a crucible rotary lift mechanism 38 provided outside the furnace body 12 and extending through the bottom of the furnace body 12.

The heat shield 20 is held above the crucible 14 via a heat shield supporting member 42 mounted on the upper surface of the second heat insulating member 24.

A carrier gas supply unit 44 for supplying the carrier gas G1 into the furnace body 12 via a butterfly valve 43 is connected to the carrier gas inlet 28. A carrier gas outlet unit 48 for exhausting the carrier gas G1 come through the inner periphery of the heat shield 20 and between the heat shield 20 and the silicon melt 16 via a butterfly valve 46 is connected to the outlet 26. A supply amount of the carrier gas G1 to be supplied into the furnace body 12 is controlled by controlling the butterfly valve 43, and an exhaust amount of exhaust gas (including the carrier gas G1 and gas generated from the silicon melt 16 such as SiOx gas) to be exhausted from the furnace body 12 is controlled by controlling the butterfly valve 46 respectively.

Next, the method of manufacturing the silicon single crystal of the present invention will be explained.

The method of manufacturing the silicon single crystal of the present invention includes a step (S100) of melting a silicon material to be the silicon melt 16 in the furnace body 12 and a step (S200) of pulling up the silicon single crystal Ig by using the silicon single crystal pulling up apparatus 10 as shown in FIG. 1.

The step of pulling up the silicon single crystal Ig (s200) includes a step of forming a neck part 55 (S201) after bringing the seed crystal 50 held by the seed chuck 32 into contact with the silicon melt 16, a step of forming a crown part Ig1 (S202) by enlarging the neck part 55 to a desired crystal diameter, a step of forming a straight body Ig2 (S203) by controlling a crystal diameter to be the above-mentioned desired diameter and a step of forming a tail part Ig3 (S204) by reducing the above-mentioned desired diameter.

The method of manufacturing the silicon single crystal of the present invention is characterized in that after melting the silicon material (after S100) and before the start of pulling up the silicon single crystal (before S200), a heater power and an internal furnace pressure are maintained for a predetermined time (S300) such that the heater power is higher than that during the step of pulling up the silicon single crystal and the internal furnace pressure is lower than that during the step of pulling up the silicon single crystal, and then the step of pulling up the silicon single crystal is carried out after step S300.

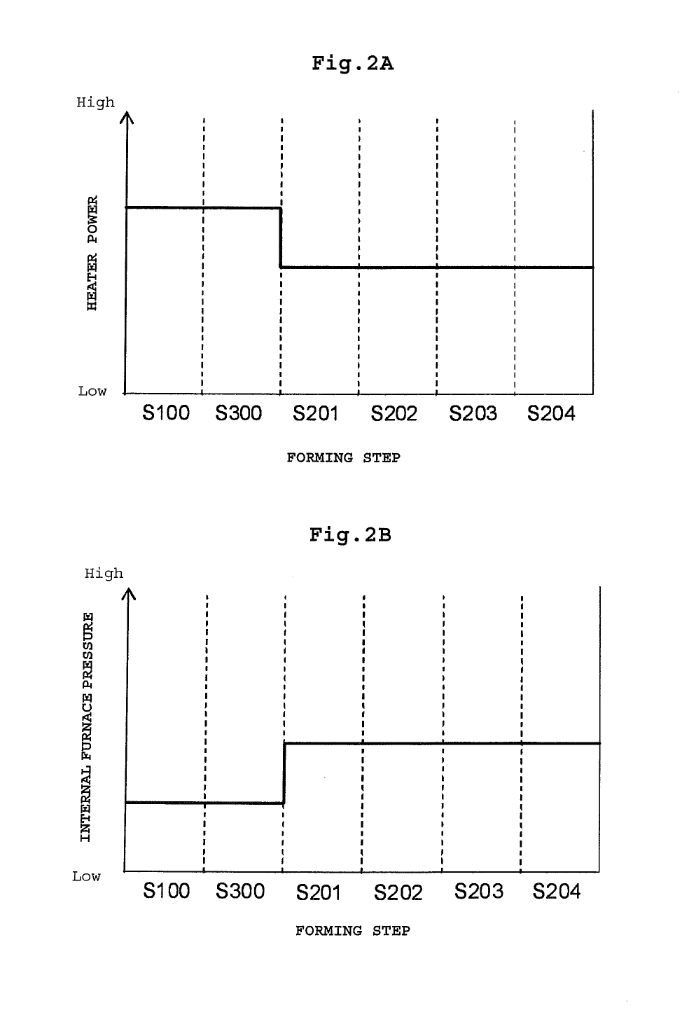

Specifically, heater power output and internal furnace pressure control as shown in FIGS. 2A and 2B are carried out.

The inventor believes that a mechanism for a pinhole formation in a silicon single crystal is described as follows:

During the melting of the silicon material, carrier gas (mainly Ar gas) remains as a gas bubble in a cavity (defect) existing in an inner wall of a quartz crucible. After melting the silicon material, at a boundary triple point of the gas bubble, silicon melt and quartz crucible, following reaction takes place: SiO₂ (S)→2Osi+Si (L) and Si (L)+Osi→SiO (G) (S: solid, L: liquid, G: gas, Osi: Oxygen dissolved in silicon melt). The above-mentioned gas bubble is caused to expand by the generated SiO gas. Thereafter, if a diameter of the expanded gas bubble becomes larger than a critical diameter, balance between a contact angle of the quartz crucible and buoyancy is disturbed, thereby allowing the gas bubble to release from the inner wall of the quartz crucible. Pinholes are believed to form due to the released gas bubble being trapped into the silicon single crystal.

Therefore, after the melting of the silicon material (after S100) and before the start of pulling up the silicon single crystal (before S200), the gas bubbles are expanded and released from the inside of the cavity by increasing a temperature of the inner wall surface of the quartz crucible to above a temperature during the pulling up of the silicon single crystal and reducing the internal furnace pressure to below the pressure during the pulling up of the silicon single crystal. The inside of the cavity is thereby filled with the silicon melt and the SiO resulted from melting of the quartz crucible is dissolved directly in the silicon melt and diffused. Therefore, no gas bubble as described above is generated and it is possible to more greatly suppress the pinhole formation in the silicon single crystal during the pulling up of the silicon single crystal.

It is to be noted that the reason for causing the cavity to exist in the inner wall of the quartz crucible can be considered as follows. That is, open pores present in a state in which bubbles originally exist in a surface layer of the inner wall of the quartz crucible are exposed to the surface, scratches generated when filling the silicon material in the quartz crucible, defects generated by reduction of viscosity of the quartz crucible during the melting of the silicon material and penetration of the silicon material into the inner wall of the quartz crucible or the like. The present invention has a great advantage of suppressing the pinhole formation efficiently in such a case where the cavity exists in the inner wall of the quartz crucible.

The temperature of the inner wall surface of the quartz crucible can be increased to above the temperature during the pulling up of the silicon single crystal by increasing the heater power to above the heater power during the pulling up of the silicon single crystal. In addition, the internal furnace pressure can be decreased to below the pressure during the pulling up of the silicon single crystal in a well-known manner. For example, in the case of using the single crystal pulling up apparatus 10 as shown in FIG. 1, the internal furnace pressure can be controlled by controlling a supply amount of the carrier gas by the butterfly valves 43 and 46 or using a vacuum pump (not shown) separately mounted to the furnace body 12.

If the heater power in step S300 is equal to or lower than the heater power during the pulling up of the silicon single crystal (during S200), the effect of expanding the gas bubble is small, thus it is difficult to more greatly suppress the pinhole formation in the silicon single crystal.

In addition, if the internal furnace pressure in step S300 is equal to or higher than the pressure during the pulling up of the silicon single crystal (during S200), the effect of expanding the gas bubble is small, thus it is difficult to more greatly suppress the pinhole formation in the silicon single crystal.

When maintaining the internal furnace pressure for a predetermined time as described above, the internal furnace pressure is preferably equal to or lower than 30 Torr.

If the internal furnace pressure is higher than 30 Torr, the effect of expanding the gas bubble is small, thus it is difficult to more greatly suppress the pinhole formation in the silicon single crystal.

A lower limit of the above-mentioned internal furnace pressure is preferably 10 Torr or more which is utilization limit as a structural characteristic of the furnace.

The heater power which is higher than the heater power during the pulling up of the silicon single crystal after the melting of the silicon material (after S100) and before the start of pulling up the silicon single crystal (before S200) is preferably from 101 to 120 when the heater power during the pulling up of the silicon single crystal is expressed as 100. That is, the heater power at step S300 is preferably from 1 to 20% higher than that during the pulling up of the silicon single crystal.

If the above-mentioned heater power is less than 1%, the effect of expanding the gas bubbles is small, thus it may be difficult to more greatly suppress the pinhole formation in the silicon single crystal. If the above-mentioned heater power is higher than 20%, the amount of SiO generated from the silicon melt will be increased before the above-mentioned pulling up of the silicon single crystal, and a deposited SiO material is heavily adhered to a carbon member used as a hot zone in the silicon single crystal pulling up apparatus and dislocation can be caused thereby. Therefore, it is not preferred.

The above-mentioned predetermined time is preferably from 0.5 to 60 minutes.

If the above-mentioned time is shorter than 0.5 minute, it is not preferred because it may become impossible to achieve full effectiveness of removing the gas bubble from the cavity. If the above-mentioned time is longer than 60 minutes, the deposited SiO material is heavily adhered to the carbon member used as the hot zone in the silicon single crystal pulling up apparatus and dislocation can be caused thereby. Therefore, it is not preferred.

The internal furnace pressure during the above-mentioned pulling up of the silicon single crystal (during S200) is preferably higher than that in the above-mentioned step S300 and not higher than 100 Torr.

By increasing the internal furnace pressure to above the pressure during the above-mentioned step S300, effect of the expansion of the gas bubble during the step 300 can be stopped or decreased and solubility of a gas component in the silicon melt can be increased. Thus, generation of the gas bubble can be suppressed and the pinhole formation in the silicon single crystal can be suppressed more greatly.

If the above-mentioned internal furnace pressure is higher than 100 Torr, high internal furnace pressure may disturb atmosphere gas distribution of the inner furnace, worsen contamination in the furnace body 12 and cause dislocation in the silicon single crystal, thus it is not preferred.

A lower limit of the internal furnace pressure during the above-mentioned pulling up of the silicon single crystal (during S200) is preferably not lower than 40 Torr.

This internal furnace pressure range can ensure a great suppression of the pinhole formation.

In the above-mentioned step S300, the number of rotations of the crucible 14 containing the silicon melt 16 is preferably larger than the number of rotations during the above-mentioned step S100 (if not rotating the crucible 14 during the melting of the silicon material, the crucible is rotated, and if rotating the crucible 14 during the melting of the silicon material, the number of rotations is increased).

It is more preferable that the use of such a method allows removing the generated gas bubble from the silicon melt efficiently.

The above-mentioned number of rotations of the crucible is preferably not smaller than 10 rpm and not larger than 30 rpm.

The heater power and internal furnace pressure control in the method of manufacturing the silicon single crystal of the present invention have been explained with reference to the embodiment shown in FIGS. 2A and 2B, but the present invention is not limited thereto. The higher or lower heater power or internal furnace pressure during step S100 than those during step S300 may also be applied.

In addition, in the step of pulling up the above-mentioned silicon single crystal Ig (S200), the embodiment that includes the step of forming the tail part Ig3 (S204) has been explained, but the present invention is not limited thereto. The present invention may also be applied to a manufacturing method of tailless silicon single crystal not including step S204.

### EXAMPLES

The present invention will be further described with reference to Examples, but the present invention is not limited thereto.

### Experiment 1

A P-type silicon single crystal Ig having a straight body Ig2 having a crystal orientation of <100> and a diameter of 310 mm was manufactured from 300 kg of silicon material by using the silicon single crystal pulling up apparatus 10 shown in FIG. 1.

At this time, the heater power control and the internal furnace pressure control as shown in FIGS. 2A and 2B were carried out such that after the melting of the silicon material and before starting the pulling up of the silicon single crystal (step S300), the heater power was increased by 5% compared to that during the pulling up of the silicon single crystal and the silicon melt was held under various conditions by changing the internal furnace pressure and a period of time for maintaining the pressure level. The heater power level was then turned back and the internal furnace pressure was set at 80 Torr. Ten silicon single crystals were pulled up for each condition (Examples from 1 to 7, Comparative example 1).

In addition, 10 silicon single crystals were pulled up under the same condition as those in Example 7 but not increasing the heater power in step S300 and maintaining the same heater power as that during the pulling up of the silicon single crystal (Comparative example 2).

The straight body Ig2 of the thus obtained silicon single crystal Ig was processed into silicon wafers by known processes. Incidence of the pinhole formation was then evaluated for each condition by evaluating pinholes of all wafers. In this evaluation, if any pinhole has been confirmed in a wafer plane, the evaluation was regarded as no good.

Similarly, incidence of melt-back during the pulling up of the silicon single crystal was also evaluated. The incidence of melt-back was such that once the melt-back was performed during the pulling up of the silicon single crystal, the melt-back was deemed to have taken place, and incidence per 10 silicon single crystals was evaluated.

Experiment conditions and evaluation results of this experiment are shown in Table 1.

TABLE 1

| | Internal | | | |
|---|---|---|---|---|
| | furnace | | Incidence of | Incidence |
| | pressure at | Holding | pinhole | of |
| | step S300 | Time | formation | melt-back |
| | (Torr) | (mins) | (%) | (%) |
| Example 1 | 10 | 0.5 | 0.4 | 20 |
| Example 2 | 10 | 2 | 0.3 | 10 |
| Example 3 | 20 | 0.5 | 0.3 | 20 |
| Example 4 | 20 | 60 | 0.2 | 20 |
| Example 5 | 30 | 0.5 | 0.3 | 10 |
| Example 6 | 30 | 2 | 0.3 | 30 |
| Example 7 | 30 | 60 | 0.2 | 20 |
| Comparative example 1 | 50 | 60 | 4.5 | 60 |
| Comparative example 2 | 30 | 60 | 4 | 50 |

As shown in Table 1, by increasing the heater temperature during step S300 to above the temperature during the pulling up of the silicon single crystal and setting the internal furnace pressure as 30 Torr or less, it was confirmed that both the incidence of pinhole formation and the incidence of melt-back decreased. It is to be noted that if the internal furnace pressure (Torr) during step S300 is higher than 30 Torr (Comparative example 1) or if the heater power is not increased in step S300 (Comparative example 2), high incidence of pinhole formation and melt-back was confirmed for both cases.

### Experiment 2

A P-type silicon single crystal Ig having a straight body Ig2 having a crystal orientation of <100> and a diameter of 310 mm was manufactured from 300 kg of the silicon material by using the silicon single crystal pulling up apparatus 10 shown in FIG. 1.

At this time, the heater power output control and the internal furnace pressure control as shown in FIGS. 2A and 2B were carried out such that after the melting of the silicon material and before starting the pulling up of the silicon single crystal (step S300), the heater power was increased by 5% compared to the heater power during the pulling up of the silicon single crystal and the silicon melt was held under various conditions by changing the internal furnace pressure and a period of time for maintaining the pressure level. The heater power level was then turned back and the internal furnace pressure was set at 40 Torr. Ten silicon single crystals were pulled up for each condition (Examples from 8 to 14, Comparative example 3).

In addition, 10 silicon single crystals were pulled up under the same condition as those in the Example 14 but not increasing the heater power in step S300 and maintaining the same heater power as that during the pulling up of the silicon single crystal (Comparative example 4).

The straight body Ig2 of the thus obtained silicon single crystal Ig was processed into the silicon wafers by known processes. Incidence of pinhole formation was then evaluated for each condition by evaluating pinholes of all wafers. In this evaluation, if any pinhole has been confirmed in a wafer plane, the evaluation was regarded as no good.

Similarly, incidence of melt-back during the pulling up of the silicon single crystal was also evaluated. The incidence of melt-back was such that once the melt-back was performed during the pulling up of the silicon single crystal, the melt-back was deemed to have taken place, and incidence per 10 silicon single crystals was evaluated.

Experiment conditions and evaluation results of this experiment are shown in Table 2.

TABLE 2

| | Internal | | | |
|---|---|---|---|---|
| | furnace | | Incidence of | Incidence |
| | pressure at | Holding | pinhole | of |
| | step S300 | Time | formation | melt-back |
| | (Torr) | (mins) | (%) | (%) |
| Example 8 | 10 | 0.5 | 0.5 | 20 |
| Example 9 | 10 | 2 | 0.4 | 10 |
| Example 10 | 20 | 0.5 | 0.4 | 20 |
| Example 11 | 20 | 60 | 0.2 | 10 |
| Example 12 | 30 | 0.5 | 0.3 | 10 |
| Example 13 | 30 | 2 | 0.4 | 20 |
| Example 14 | 30 | 60 | 0.3 | 20 |
| Comparative example 3 | 50 | 60 | 5.5 | 60 |
| Comparative example 4 | 30 | 60 | 5 | 50 |

As shown in Table 2, similarly to Experiment 1, by increasing the heater temperature during step S300 to above the temperature during the pulling up of the silicon single crystal and setting the internal furnace pressure as 30 Torr or less, it was confirmed that both the incidence of pinhole formation and the incidence of melt-back decreased. It is to be noted that if the internal furnace pressure (Torr) during step S300 is higher than 30 Torr (Comparative example 3) or if the heater power is not increased in step S300 (Comparative example 4), high incidence of the pinhole formation and melt-back was confirmed for both cases.

What is claimed is:

1. A method of manufacturing a silicon single crystal by the Czochralski method which comprises a step of melting a silicon material to be silicon melt in a furnace body and then a step of pulling up the silicon single crystal, wherein after the step of melting said silicon material and before the start of the step of pulling up said silicon single crystal, a heater power is set to be higher than that during the step of pulling up said silicon single crystal, and an internal furnace pressure is set as 30 Torr or less which is lower than that during the step of pulling up said silicon single crystal, said power and pressure being maintained for a predetermined time, and then the step of pulling up said silicon single crystal is carried out.

2. The method as claimed in claim 1, wherein said predetermined time is from 0.5 to 60 minutes.

3. The method as claimed in claim 1, wherein said internal furnace pressure during the step of pulling up said silicon single crystal is not more than 100 Torr.

4. The method as claimed in claim 2, wherein said internal furnace pressure during the step of pulling up said silicon single crystal is not more than 100 Torr.
